(19) United States
(12) Patent Application Publication
(10) Pub. No.: US 2019/0287939 A1
(43) Pub. Date: Sep. 19, 2019

(54) SEMICONDUCTOR DEVICE AND FABRICATING METHOD OF THE SAME

(71) Applicant: TOSHIBA MEMORY CORPORATION, Tokyo (JP)

(72) Inventor: Yasuo TAKEMOTO, Kamakura Kanagawa (JP)

(21) Appl. No.: 16/115,263

(22) Filed: Aug. 28, 2018

(30) Foreign Application Priority Data
Mar. 19, 2018 (JP) 2018-050484

(51) Int. Cl. H01L 23/00; H01L 25/065; H01L 25/18; H01L 23/10; H01L 25/00

(52) U.S. Cl. CPC H01L 24/49; H01L 2924/14511; H01L 25/18; H01L 23/10; H01L 24/73; H01L 24/17; H01L 24/33; H01L 25/50; H01L 24/83; H01L 24/81; H01L 24/85; H01L 24/97; H01L 24/92; H01L 2924/381; H01L 2224/73253; H01L 2224/73207; H01L 2224/73215; H01L 2224/92143; H01L 25/0657

(57) ABSTRACT

A semiconductor device includes a first substrate having a first face and a second face, a first semiconductor chip on the first face, a first wire which electrically connects the first semiconductor chip and the first substrate, a first resin which seals the first semiconductor chip and the first wire, a first metal bump on the second face, a second substrate below the first substrate, the second substrate having a third face and a fourth face, a second semiconductor chip on the third face and electrically connected to the first metal bump, a second wire which electrically connects the second semiconductor chip and the second substrate, a second resin between the second face and the third face, the second resin sealing the first metal bump, the second semiconductor chip and the second wire, and a second metal bump on the fourth face.

### CROSS-REFERENCE TO RELATED APPLICATION

This application is based upon and claims the benefit of priority from Japanese Patent Application No. 2018-050484, filed Mar. 19, 2018, the entire contents of which are incorporated herein by reference.

### FIELD

Embodiments described herein relate generally to a semiconductor device and a fabricating method of the same.

### BACKGROUND

A semiconductor memory such as a NAND Electrically Erasable Programmable Read-Only Memory (EEPROM) is manufactured by stacking memory chips on a substrate, and connecting the memory chips and the substrate with metal wires. When the number of stacked memory chips is increased, the number of bonding metal wires is also increased. Therefore, it becomes necessary to provide a larger area for wire bonding on the substrate to prevent interference between wire bonding tools (e.g., the wire bonding tool capillary) and the already existing bonded metal wires.

It is also possible to increase the number of stacked memory chips by stacking multi-chip packages in an overlapping manner with a Package On Package (POP) method. However, in this case, while the wire bonding area on the substrate can be made relatively small, there is a need to set aside a dedicated area to connect the multi-chip packages in a region having no other semiconductor chip and an area for connecting the semiconductor packages to each other.

### DESCRIPTION OF THE DRAWINGS

FIG. 1 is a cross-sectional view depicting a semiconductor memory according to a first embodiment.

FIGS. 2A and 2B are cross-sectional views depicting aspects of a fabricating method of a semiconductor memory according to a first embodiment.

FIGS. 3A and 3B are cross-sectional views depicting further aspects of a fabricating method of the semiconductor memory.

FIGS. 4A and 4B are cross-sectional views depicting further aspects of a fabricating method of the semiconductor memory.

FIGS. 5A and 5B are cross-sectional views depicting further aspects of a fabricating method of the semiconductor memory.

FIGS. 6A and 6B are cross-sectional views depicting further aspects of a fabricating method of the semiconductor memory.

FIG. 7 is a cross-sectional view depicting a semiconductor memory according to a second embodiment.

FIG. 8 is a cross-sectional view depicting a semiconductor memory according to a third embodiment.

### DETAILED DESCRIPTION

In general, according to one embodiment, a semiconductor device includes a first substrate having a first face and a second face opposite the first face, a first semiconductor chip on the first face of the first substrate, a first wire which electrically connects the first semiconductor chip and the first substrate, a first resin which seals the first semiconductor chip and the first wire, a first metal bump on the second face, a second substrate below the first substrate, the second substrate having a third face and a fourth face opposite to the third face, a second semiconductor chip on the third face and electrically connected to the first metal bump, a second wire which electrically connects the second semiconductor chip and the second substrate, a second resin between the second face of the first substrate and the third face of the second substrate, the second resin sealing the first metal bump, the second semiconductor chip and the second wire, and a second metal bump on the fourth face.

Hereinafter, example embodiments of the present disclosure will be described with reference to the drawings. The present disclosure is not limited to these example embodiments. In the following description, an up-down direction or side of the substrate refers to a relative direction in which the mounting surface of the semiconductor chip faces upward, but this direction may be different from the up-down direction corresponding to the direction of gravitational acceleration. The drawings are schematic and conceptual, and as such depicted ratios between the respective portions are not necessarily illustrated according to sizes in an actual device. In the specification and the drawings, the same reference symbol will be attached to the same elements and once described in reference to a drawing or otherwise repeated description may be omitted.

### First Embodiment

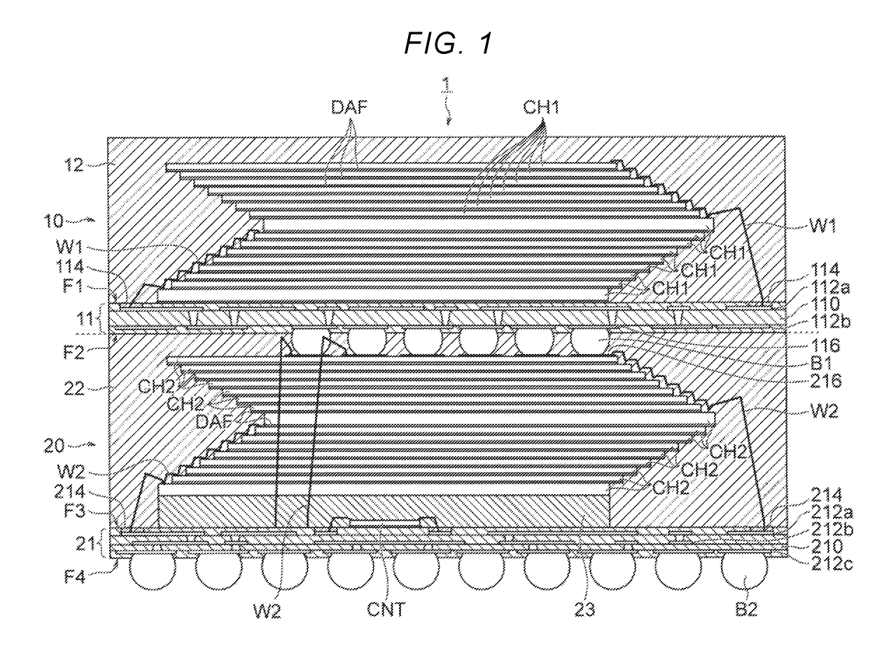

FIG. 1 is a cross-sectional view illustrating a semiconductor memory 1 according to a first embodiment. The semiconductor memory 1 includes a first package 10 and a second package 20. The first package 10 includes a first substrate 11, first semiconductor chips CH1, first wires W1, a first resin 12, and first metal bumps B1. The second package 20 includes a second substrate 21, second semiconductor chips CH2, a second resin 22, second metal bumps B2, and a memory controller CNT.

Configuration of First Package 10

The first substrate 11 includes wiring layers 112a and 112b, a resin layer 110, and electrode pads 114. The wiring layers 112a and 112b are wirings to electrically connect an electrode pad 114 and a first metal bump B1. In the wiring layers 112a and 112b, for example, conductive metal such as copper and tungsten is used. The resin layer 110 is provided between the wiring layers 112a and 112b, and/or on the surfaces of these layers. For the resin layer 110, an insulating material such as a glass epoxy resin is used, for example.

On a first face F1 of the first substrate 11, several first semiconductor chips CH1 are stacked. The first semiconductor chip CH1 on the lowest layer (bottommost semiconductor chip CH1) is bonded onto the first substrate 11 by an adhesive layer die attachment film (DAF). Then, another first semiconductor chip CH1 is bonded onto bottommost first semiconductor chip CH1 by an adhesive layer DAF. In this way, the first semiconductor chips CH1 are stacked along a longitudinal direction (a direction substantially orthogonal to the first face F1 of the substrate 11) by an adhesive layer DAF.

The first semiconductor chips CH1 are stacked in a partially offset manner to provide a stepwise shape with the chips being offset in a first direction (e.g., right hand page direction), as illustrated in FIG. 1, and then stacked to be offset in a reverse direction (e.g., left hand page direction) after some point (e.g., a midpoint) along the longitudinal direction in the stack. With this configuration, it is possible to prevent a first semiconductor chip CH1 from overlapping and blocking an electrode pad (bonding wire terminal) of another first semiconductor chip CH1 in the stack, and the first wires W1 can be connected to the electrode pad for each first semiconductor chip CH1 in the stack. The first semiconductor chips CH1 may be memory chips which each have the same configuration, for example. In a particular example, the memory chip may be a NAND EEPROM chip with memory cells which three-dimensionally arranged.

The first wires W1 are bonded between the electrode pads of the first semiconductor chips CH1 and the electrode pads 114 of the first substrate 11. The first wires W1 electrically connect the electrode pads of the first semiconductor chip CH1 and the electrode pads 114. For the first wires W1 a conductive metal such as gold can be used.

The first resin 12 seals the first semiconductor chips CH1 and the first wires W1 on the first face F1. With this configuration, the first resin 12 protects the first semiconductor chips CH1 and the first wires W1 from impacts and ambient air.

The first metal bumps B1 are provided on a second face F2 of the first substrate 11 on the opposite side to the first face F1. The first metal bumps B1 are connected to part (s) of the wiring layer 112b. The first metal bumps B1 are provided to electrically connect the first package 10 and the second package 20 to each other. The first metal bumps B1 are a conductive metal such as solder.

Configuration of Second Package 20

The second substrate 21 includes wiring layers 212a, 212b, and 212c, a resin layer 210, and electrode pads 214. The wiring layers 212a to 212c are wired to electrically connect electrode pads 214 and second metal bumps B2. The wiring layers 212a to 212c, for example, conductive metal such as copper and tungsten is used. The resin layer 210 is provided between the wiring layers 212a to 212c and on the surfaces of these layers. In the resin layer 210, for example, an insulating material such as a glass epoxy resin is used.

On a third face F3 of the second substrate 21, the memory controller CNT and second semiconductor chips CH2 are stacked. The memory controller CNT is provided below the stack of second semiconductor chips CH2 and covered by a resin layer 23. The memory controller CNT controls the operations of the first semiconductor chips CH1 and the second semiconductor chips CH2. On a resin layer 23, the second semiconductor chips CH2 are bonded by an adhesive layer DAF. The second semiconductor chips CH2 are stacked in a longitudinal direction (a direction substantially orthogonal to the third face F3 of the substrate 21) by an adhesive layer DAF.

The second semiconductor chips CH2 are also stacked in an offset manner in a stepwise shape similarly to the first semiconductor chips CH1, and then stacked in an offset manner in the reverse direction after some point (e.g., midpoint) in the stack. With this configuration, it is possible to prevent a second semiconductor chip CH2 from overlapping and blocking the electrode pads of another second semiconductor chip CH2 in the stack, and thus the second wires W2 can be connected to the electrode pads for each second semiconductor chip CH2. The second semiconductor chips CH2 may be memory chips, each of which has the substantially the same configuration as first semiconductor chips CH1, for example.

The second wires W2 are bonded between the memory controller CNT and an electrode pad of a second semiconductor chip CH2, between electrode pads of adjacent second semiconductor chips CH2 in the stack, or between an electrode pad of a second semiconductor chip CH2 and an electrode pad 214 of the second substrate 21. The second wires W2 electrically connect the electrode pads of the second semiconductor chip CH2 and the electrode pads 214 of the second substrate 21. In the second wires W2, for example, a conductive metal such as gold is used.

The second resin 22 seals the second semiconductor chips CH2 and the second wires W2 on the third face F3. With this configuration, the second resin 22 can protect the second semiconductor chips CH2 and the second wires W2 from impacts and ambient air. In this example, the second resin 22 is provided between the second face F2 of the first substrate 11 and the third face F3 of the second substrate 21, and seals not only the second semiconductor chips CH2 and the second wires W2 but also the first metal bumps B1. In other words, the first metal bumps B1, the second semiconductor chips CH2, and the second wires W2 are sealed using the second resin 22 and is made of the same resin material as used between the second face F2 of the first substrate 11 and the third face F3 of the second substrate 21. The second resin 22 is inserted and formed in the same process between the second face F2 of the first substrate 11 and the third face F3 of the second substrate 21. Therefore, the second resin 22 can be continuously formed of the same material from the first metal bumps B1 along the second semiconductor chips CH2, and is thus integrally and seamlessly formed. In this way, the second resin 22 seals the first metal bumps B1, the second semiconductor chips CH2, and the second wires W2 using the same resin material.

The second metal bumps B2 are provided on a fourth face F4 of the second substrate 21 on an opposite side to the third face F3, and connected to part of the wiring layer 212c. The second metal bumps B2 are provided to electrically connect the semiconductor memory 1 to an external mounting substrate (not illustrated). In the second metal bump B2, for example, conductive metal such as solder is used.

On the second semiconductor chip CH2 that is on the uppermost layer of the stack, a rewiring layer 216 is provided. The rewiring layer 216 electrical connects an element in the second semiconductor chip CH2 and a first metal bump B1. The rewiring layer 216 may be electrically connected to the electrode pads 214 of the second substrate 21 by wires W2. With this configuration, the first semiconductor chips CH1 in the first package 10 and the memory controller CNT in the second package 20 can be electrically connected, and therefore the first semiconductor chips CH1 and the second semiconductor chips CH2 can together serve as the semiconductor memory 1.

In this way, the semiconductor memory 1 has a configuration similar to a POP-type device. However, in general, a POP-type device includes a pad area in the lower package to connect metal bumps of the upper package to the upper portion of a semiconductor chip. The pad area for the bumps is provided to be adjacent to a semiconductor chip of the lower package in the width direction of the chip. Therefore, inclusion of such a pad area hinders the miniaturization of a semiconductor memory structure.

In contrast, the semiconductor memory 1 according to the present embodiment is provided with the rewiring layer 216 on at least one of the second semiconductor chips CH2, and the first metal bumps B1 for the first semiconductor chips CH1 comes into contact with the rewiring layer 216. Therefore, the second package 20 does not require a dedicated connection area of the first metal bumps B1 at a position on the second substrate adjacent, in a lateral direction, to the second semiconductor chips CH2. With this configuration, it is possible to minimize the occupied planar area of the semiconductor memory 1.

In addition, since the semiconductor memory is divided into the first package 10 and the second package 20, the numbers of the semiconductor chips (CH1 and CH2) stacked in the respective packages (10 and 20) are relatively less. For example, when the number of semiconductor chips are equally divided between the first package 10 and the second package 20, stack height (number of chips in the stack) in the respective packages 10 and 20 is reduced by one half as compared to a single package containing the same total number of chips. With this configuration, the number of wires (W1 and W2) in each package (10 and 20) is reduced by a half as compared to a single package chip stack with the same total number of chips. In addition, a step height (the distance between an uppermost chip in the stack and the substrate below) between the semiconductor chips CH1 and CH2 and the substrates 11 and 21 is reduced. In general, a wire bonder utilizes a bonding capillary that is narrow at its tip end (end at which the bonding wire emerges) but which becomes thicker a “root portion” away from the tip end. Therefore, when the chip stack height increases, the thicker root portion of the bonding capillary may come into contact with the chip stack if the bonding is performed too near the stack in the lateral direction. Thus, to prevent interference with bonding tool, there is a need to separate the bonding pads from the chip stack by some amount. In this case, the minimization of the substrates 11 and 12 would be hindered. In contrast, according to the present embodiment, the step height of the chip stacks in the respective packages 10 and 20 is reduced. With this configuration, the bonding capillary hardly interferes with the semiconductor chip stacks and the previously formed wires W1 and W2, and additional wires can be easily connected. Therefore, there is no need to further separate the bonding pads on the substrates 11 and 21 from the stacked semiconductor chips CH1 and CH2. As a result, it is possible to form a narrow bonding area on the substrates 11 and 21, which permits minimization of the semiconductor memory 1 size.

In addition, the second resin 22 continues from the first metal bump B1 along the second semiconductor chip CH2, and is integrally and seamlessly formed. The second resin 22 seals the first metal bumps B1, the second semiconductor chips CH2, and the second wires W2 using resin. With this configuration, the second resin 22 can sufficiently protect the connection between the first metal bumps B1 and the rewiring layer 216. This configuration leads to an improvement in reliability of the semiconductor memory 1.

If the first metal bumps B1 are not covered by resin, the first metal bumps B1 will not be sufficiently protected, and the reliability of the semiconductor memory 1 will be lowered. In addition, in a case where an additional resin (besides the second resin 22) would be injected between the first package 10 and the second package 20, a boundary would be generated between the second resin and this additional resin. With such a configuration, the protection for the connection between the first metal bumps B1 and the rewiring layer 216 would be lowered. In addition, in a case where a specialized resin material would be used as the additional resin in order not to provide a lower the protection strength, then material costs and fabricating costs would be increased because additional procedures for forming the additional resin would be necessary. Therefore, productivity is lowered.

In contrast, according to the present embodiment, the second resin 22 continues from the first metal bump B1 along the second semiconductor chip CH2, and is this integrally and seamlessly formed. With this configuration, the second resin 22 can provide high protection strength for the connection between the first metal bumps B1 and the rewiring layer 216.

In addition, as further described below, the second resin 22 is formed after the first metal bumps B1 are connected to the rewiring layer 216. Therefore, the first metal bumps B1 do not become narrowed or deformed by any influence of the second resin 22. With this configuration, the reliability of the semiconductor memory 1 is improved still more.

Next, a fabricating method of the semiconductor memory 1 according to the first embodiment will be described.

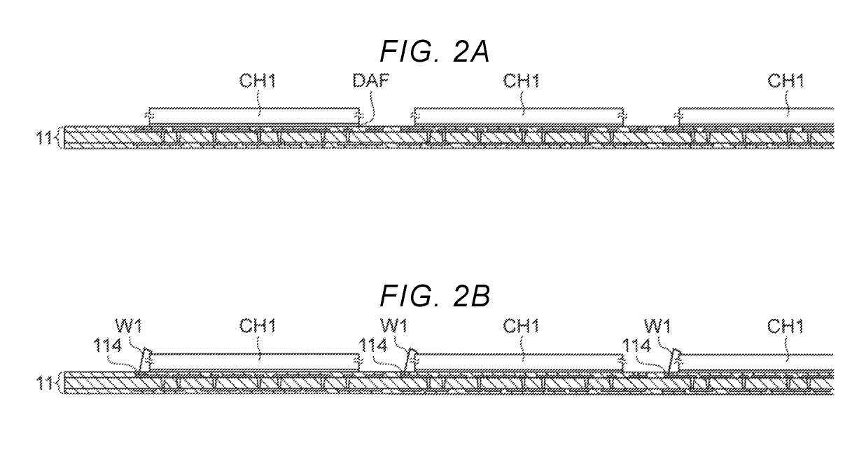

FIGS. 2A to 6B are cross-sectional views illustrating an example of a fabricating method of a semiconductor memory 1 according to the first embodiment.

First, as illustrated in FIG. 2A, the first substrate 11 is prepared. Next, the first semiconductor chips CH1 are stacked on the first substrate 11. The first semiconductor chips CH1 are bonded to the first substrate 11 or onto the previous first semiconductor chip CH1 using an adhesive layer DAF. In addition, the first semiconductor chips CH1 are stacked in an offset manner to form a stepwise shape as was described with reference to FIG. 1. In the depictions, the first substrate 11 is not yet diced, and stacked bodies of the first semiconductor chips CH1 are formed/mounted on the undiced substrate 11. Furthermore, note that in these figures, the structural details of the stacked bodies formed of the first semiconductor chip CH1 are omitted and just a single semiconductor chip CH1 is illustrated as representative for an entire chip stack for the sake of convenience. The structural details of these stacked bodies are shown in FIG. 1.

Next, as illustrated in FIG. 2B, the electrode pads of the first semiconductor chips CH1 and the electrode pads 114 of the first substrate 11 are connected by the first wires W1.

At this time, as was described above, the number of stacked first semiconductor chips CH1 is less than the total number of first semiconductor chips CH1 and second semiconductor chips CH2 in the finished device stack. Therefore, even though the bonding area provided on the first substrate 11 is relatively narrow, the bonding capillary used in forming the first wires W1 need not interfere/contact already formed first wires W1.

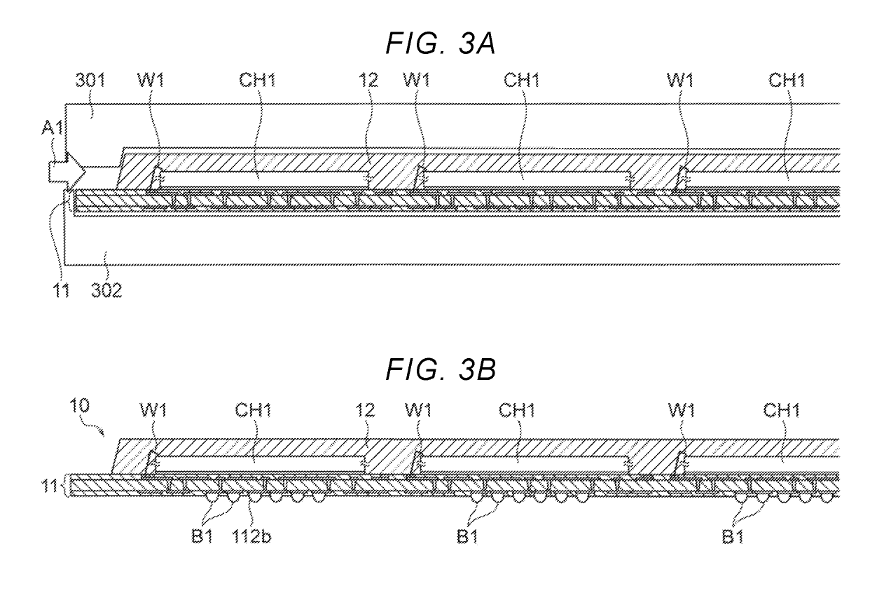

Next, as illustrated in FIG. 3A, the first substrate 11 is disposed within mold portions 301 and 302. As illustrated with an arrow A1, the first resin 12 is injected in the cavity formed between the mold portions 301 and 302. With this configuration, the first semiconductor chips CH1 and the first wires W1 are sealed by the first resin 12 on the first substrate 11, and form the first package 10.

Next, as illustrated in FIG. 3B, the first metal bumps B1 are formed on the second face F2 of the first substrate 11. The first metal bumps B1 are connected to the wiring layers 112b which includes electrode pads on the second face F2.

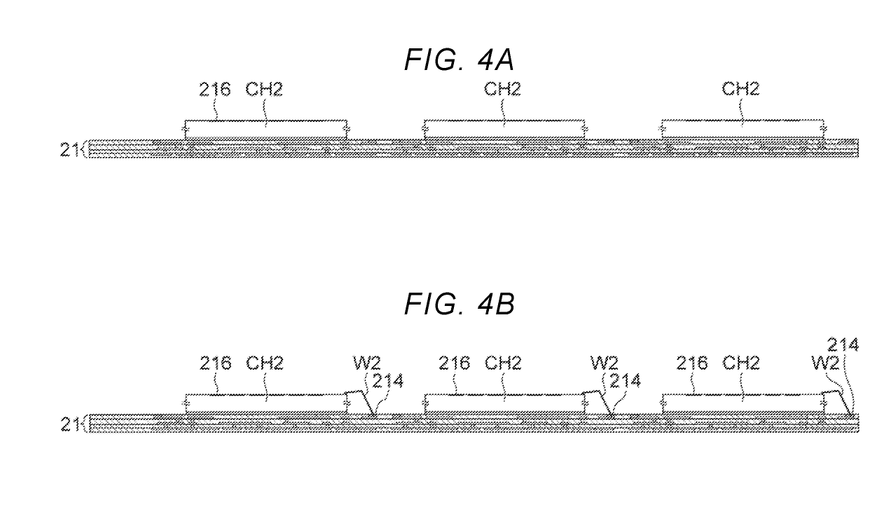

In parallel with the formation of the first package 10, or before and after the formation thereof, a manufacture process of the second substrate 21, illustrated in FIGS. 4A and 4B, can be performed.

First, the memory controller CNT is mounted on the second substrate 21. The memory controller CNT is bonded onto the second substrate 21 using an adhesive layer DAF. The second semiconductor chip CH2 of the lowest layer of the stack is placed on the memory controller CNT after the memory controller CNT has been sealed with the resin layer 23. Note that the memory controller CNT and the resin layer 23 are not separately illustrated in FIGS. 4A to 6B for the sake of explanatory convenience, though each is present with the stack of second semiconductor chips CH2 as was depicted in FIG. 1.

The second semiconductor chips CH2 are then stacked on each other. The second semiconductor chips CH2 are bonded to the one below using an adhesive layer DAF. In addition, the second semiconductor chips CH2 are stacked in an offset manner in a stepwise shape as was described with reference to FIG. 1. At this time, the second substrate 21 has not yet been diced, and the second semiconductor chip CH2 are stacked on the undiced substrate 21. In the uppermost second semiconductor chip CH2 in the stack, has the rewiring layer 216 formed on its upper surface. Note, in FIGS. 4A to 6B, for the sake of convenience, the stacked body (including the memory controller CNT therein) is omitted, and is represented by a single semiconductor chip CH2.

Next, as illustrated in FIG. 4B, the electrode pads of the second semiconductor chips CH2 and the electrode pads 214 on the second substrate 21 are connected by the second wires W2. At this time, the bonding tool (e.g., capillary) can form the second wires W2 between the second semiconductor chips CH2 and the second substrate 21 without interference from previously formed second wires W2 since relatively few second semiconductor chips CH2 are included in the stack.

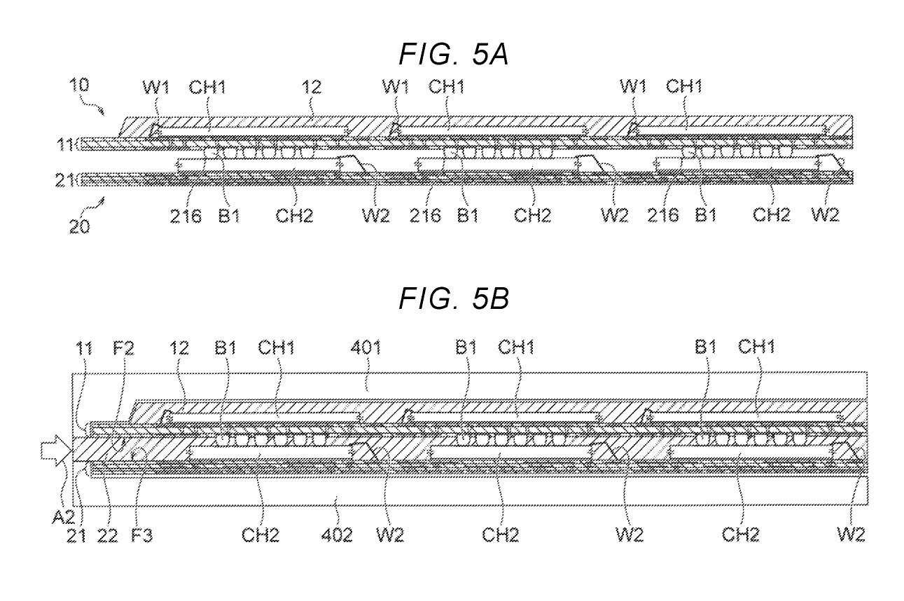

Next, as illustrated in FIG. 5A, the package 10 is placed on the second semiconductor chips CH2 to bring the first metal bumps B1 in contact with the rewiring layers 216 of the second semiconductor chips CH2. The first metal bumps B1 and the rewiring layers 216 are connected through thermal processing. At this time, the second semiconductor chips CH2 and the second wires W2 are not yet sealed with resin. Therefore, the first metal bumps B1 can be electrically connected to the rewiring layers 216 of the second semiconductor chips CH2 without depending on the position and formation of openings in the second resin 22.

Next, as illustrated in FIG. 5B, the first substrate 11 is disposed within molds 401 and 402, and the second resin 22 is injected into a cavity formed between the molds 401 and 402 as illustrated by arrow A2. With this configuration, the second resin 22 fills between the second face F2 of the first substrate 11 and the third face F3 of the second substrate 21 so as to seal the first metal bumps B1, the second semiconductor chips CH2 and the second wires W2. This, the first metal bumps B1 of the first package 10 are sealed with the second resin 22 almost at the same time and in the same procedure as used to seal the second semiconductor chips CH2 and the second wires W2 in the second package 20. Therefore, the first metal bumps B1, and the second semiconductor chips CH2 and the second wires W2 are integrally sealed using the second resin 22. The second resin 22 integrally and seamlessly seals the first metal bumps B1, the second semiconductor chips CH2, and the second wires W2. In other words, the second resin 22 between the metal bumps B1 and the second semiconductor chips CH2 or the second wires W2 has no boundary or seam.

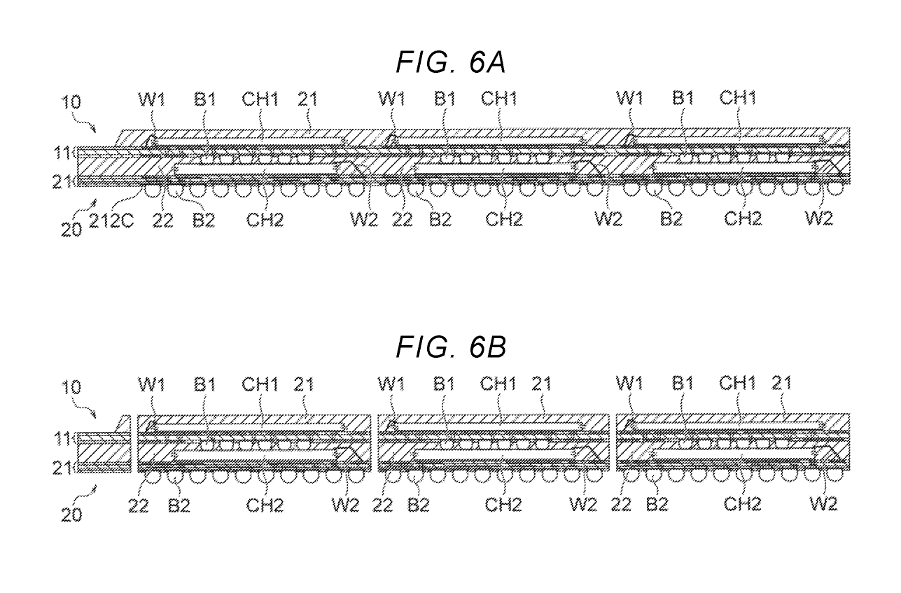

Next, as illustrated in FIG. 6A, the second metal bumps B2 are formed on the fourth face F4 of the second substrate 21. The second metal bumps B2 are connected to the wiring layer 212c, which includes electrode pads, on the fourth face F4.

Next, as illustrated in FIG. 6B, the first substrate 11 and the second substrate 21 are cut with a dicing blade. The dicing blade cuts the first substrate 11, the second substrate 21, the first resin 12, and the second resin 22 between the depicted stacks of the first and second semiconductor chips CH1 and CH2. With this configuration, the semiconductor memory 1 is diced into individual packages. In this way, the semiconductor memory 1 illustrated in FIG. 1 is formed. Furthermore, FIG. 6B illustrates three packaged semiconductor memories 1. However, this is not a limitation and four or more packages may be formed in the same process.

According to the first embodiment as described above, the second resin 22 is continuous from the first metal bumps B1 along the second semiconductor chips CH2, and is integrally and seamlessly formed. The second resin 22 protects the second semiconductor chips CH2 and the second wires W2, and also protects the first metal bumps B1. With this configuration, the second resin 22 can provide a high protection strength for the connection between the first metal bumps B1 and the rewiring layers 216, and the reliability of the semiconductor memory 1 can be improved.

In addition, the second resin 22 is formed after the first metal bumps B1 are connected to the rewiring layers 216. Therefore, the first metal bumps B1 do not become narrowed or deformed by the influence of the second resin 22. With this configuration, the reliability of the semiconductor memory 1 is improved still more.

In addition, according to the first embodiment, the semiconductor memory is divided into a first package 10 and a second package 20 so that the individual numbers of the semiconductor chips CH1 and CH2 stacked in the respective packages 10 and 20 are less than the total number of semiconductor chips in the final device. With this configuration, the bonding wire process can be performed without substantial interference resulting from higher density that would otherwise result. Therefore, the bonding area of the substrates 11 and 21 can be made narrower, so that the semiconductor memory 1 can be minimized.

Further, the first metal bump B1 of the first semiconductor chip CH1 is connected to the rewiring layer 216 on the second semiconductor chip CH2. Therefore, the second package 20 does not need to be provided with the pad area in the lateral direction of the second semiconductor chip CH2, so that the semiconductor memory 1 can be miniaturized still more.

### Second Embodiment

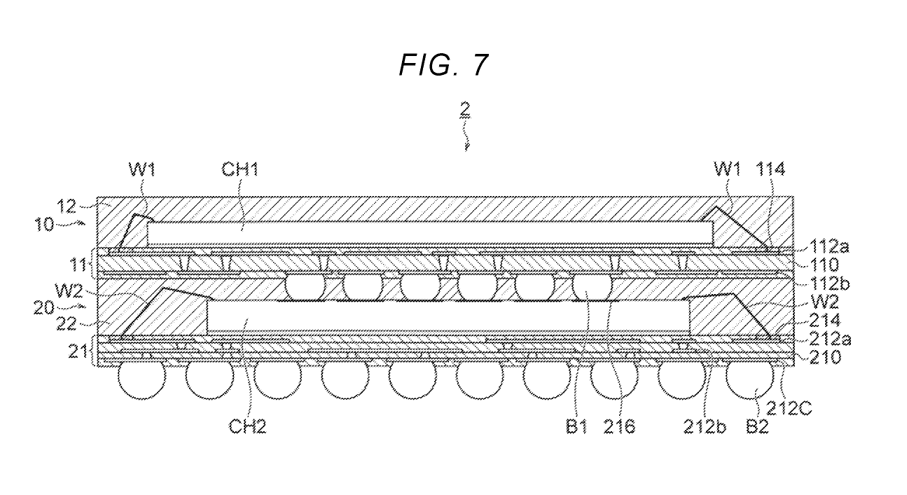

FIG. 7 is a cross-sectional view illustrating a semiconductor memory 2 according to a second embodiment. The semiconductor memory 2 according to the second embodiment includes a single first semiconductor chip CH1 in the first package 10, and includes a single second semiconductor chip CH2 in the second package 20. The rewiring layer 216 is provided on the second semiconductor chip CH2. The other configurations according to the second embodiment may be similar to those according to the first embodiment. Therefore, a semiconductor memory according to the second embodiment can obtain the similar effects to a semiconductor memory according to the first embodiment. In this way, the first and second packages 10 and 20 each may include one of each of semiconductor chips CH1 and CH2.

### Third Embodiment

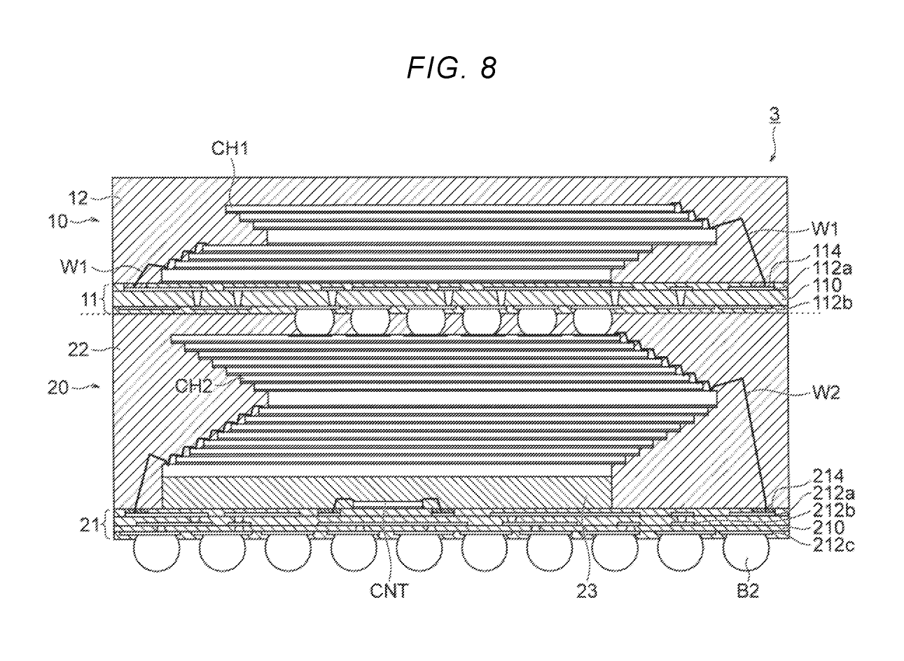

FIG. 8 is a cross-sectional view illustrating a semiconductor memory 3 according to a third embodiment. The number of first semiconductor chips CH1 in the first package 10 and the number of second semiconductor chips CH2 in the second package 20 may be equal. However, in the semiconductor memory 3 according to the third embodiment, the number of first semiconductor chips CH1 in the first package 10 may be different from the number of second semiconductor chips CH2 in the second package 20.

The other configurations according to the third embodiment may be similar to those according to the first embodiment. Therefore, a semiconductor memory according to the third embodiment can obtain the similar effect to a semiconductor memory according to the first embodiment.

As described in the third embodiment, it is possible to fabricate the semiconductor memory 1 having various data capacitance in a relatively short fabrication period by varying the numbers of semiconductor chips in the first and second packages 10 and 20. For example, the first package 10 having a predetermined number of semiconductor chips is fabricated in advance, and the second package 20 is fabricate to customize a data capacitance meeting a client's need. During this customization, the number of semiconductor chips in the second package 20 may be adjusted to set a total data capacitance of the semiconductor memory 1 to be a desired capacitance. With this configuration, when there is an order from a client, there is no need to produce both the first and second packages 10 and 20, but only the second package 20 having a desired number of semiconductor chips may be produced. With this configuration, it is possible to fabricate the semiconductor memory 1 having various data capacitances, and the productivity can be improved.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first substrate having a first face and a second face opposite the first face;
a first semiconductor chip on the first face of the first substrate;
a first wire which electrically connects the first semiconductor chip and the first substrate;
a first resin which seals the first semiconductor chip and the first wire;
a first metal bump on the second face;
a second substrate below the first substrate, the second substrate having a third face and a fourth face opposite to the third face;
a second semiconductor chip on the third face and electrically connected to the first metal bump;
a second wire which electrically connects the second semiconductor chip and the second substrate;
a second resin between the second face of the first substrate and the third face of the second substrate, the second resin sealing the first metal bump, the second semiconductor chip and the second wire; and
a second metal bump on the fourth face.

2. The semiconductor device according to claim 1, wherein the second resin is a continuous material from the first metal bump along the second semiconductor chip to the second wire at a position between the second face of the first substrate and the third face of the second substrate.

3. The semiconductor device according to claim 1, wherein the second resin extends seamlessly and integrally form the second face of the first substrate to the third face of the second substrate and seals the first metal bump, the second semiconductor chip, and the second wire.

4. The semiconductor device according to claim 1, further comprising:
a plurality of first semiconductor chips stacked on the first face of the first substrate, wherein
the plurality of first semiconductor chips is sealed with the first resin.

5. The semiconductor device according to claim 1, further comprising:
a plurality of second semiconductor chips stacked on the third face of the second substrate, wherein
the plurality of second semiconductor chips is sealed with the second resin.

6. The semiconductor device according to claim 1, further comprising:
a memory controller on the third face of the second substrate, wherein
the memory controller is sealed with a third resin, and
at least one of the first and second semiconductor chips is controlled by the memory controller.

7. The semiconductor device according to claim 1, further comprising:
a plurality of first semiconductor chips on the first face of the first substrate; and
a plurality of second semiconductor chips on the third face of the second substrate, wherein
the number of first semiconductor chips in the plurality of first semiconductor chips is different from the number of second semiconductor chips in the plurality of second semiconductor chips.

8. A semiconductor device, comprising:
a first substrate having a first face and a second face opposite the first face;
a plurality of first semiconductor chips stacked on the first face;
a plurality of first wires, each of which electrically connects a respective one of the plurality of first semiconductor chips and the first substrate;
a first resin which seals the plurality of first semiconductor chips and the plurality of first wires;
a first metal bump on the second face;
a second substrate below the first substrate, the second substrate having a third face and a fourth face opposite to the third face;
a plurality of second semiconductor chips stacked on the third face;
a plurality of second wires, each of which electrically connects a respective one of the plurality of second semiconductor chips and the second substrate;
a second resin between the second face of the first substrate and the third face of the second substrate, the second resin sealing the first metal bump, the plurality of second semiconductor chips and the plurality of second wires; and
a second metal bump on the fourth face.

9. The semiconductor device according to claim 8, wherein the first semiconductor chips are stacked in a first direction from the first substrate and are offset in a second direction from any adjacent first semiconductor chips in the stack to provide a stepped shape.

10. The semiconductor device according to claim 8, wherein the second resin is a continuous material from the first metal bump along the second semiconductor chip to the second wire at a position between the second face of the first substrate and the third face of the second substrate.

11. The semiconductor device according to claim 8, wherein
the second resin extends seamlessly and integrally form the second face of the first substrate to the third face of the second substrate and seals the first metal bump, the second semiconductor chip, and the second wire.

12. The semiconductor device according to claim 8, further comprising:
a memory controller on the third face of the second substrate, wherein
the memory controller is sealed with a third resin, and
at least one of the plurality of first semiconductor chips and the plurality of second semiconductor chips is controlled by the memory controller.

13. The semiconductor device according to claim 8, wherein
the number of first semiconductor chips in the plurality of first semiconductor chips is different from the number of second semiconductor chips in the plurality of second semiconductor chips.

14. A method of fabricating a semiconductor device, comprising:
bonding a first semiconductor chip to a first face of a first substrate;
sealing the first semiconductor chip with a first resin;
forming a first metal bump on a second face of the first substrate;
bonding a second semiconductor chip on a third face of a second substrate;
placing the first substrate on the second substrate with the first metal bump to be therebetween;
supplying a second resin to a gap between the second face of the first substrate and the third face of the second substrate and sealing the first metal bump and the second semiconductor chip with the second resin; and
dicing the first substrate, the second substrate, the first resin, and the second resin into a packaged semiconductor device.

15. The method according to claim 14, further comprising:
forming a first wire which electrically connects the first semiconductor chip and the first substrate, wherein
the first wire is sealed by the first resin.

16. The method according to claim 14, wherein the gap is completely filled with the second resin.

17. The method according to claim 14, further comprising:
bonding a memory controller to the third face of the second substrate, wherein,
at least one of the first and second semiconductor chips is controlled by the memory controller.

18. The method according to claim 14, further comprising:
stacking a plurality of first semiconductor chips on the first face of the first substrate.

19. The method according to claim 14, further comprising:
stacking a plurality of second semiconductor chips on the third face of the second substrate.

20. The method according to claim 14, further comprising:
stacking a plurality of first semiconductor chips on the first face of the first substrate; and
stacking a plurality of second semiconductor chips on the third face of the second substrate, wherein
the number of first semiconductor chips in the plurality of first semiconductor chips is different from the number of second semiconductor chips in the plurality of second semiconductor chips.
